(19) United States
(12) Patent Application Publication
(10) Pub. No.: US 2011/0149532 A1
(43) Pub. Date: Jun. 23, 2011

(54) LAMINATE, CIRCUIT BOARD AND SEMICONDUCTOR DEVICE

(75) Inventor: Akihito Takahashi, Shizuoka (JP)

(73) Assignee: SUMITOMO BAKELITE CO, LTD., Tokyo (JP)

(21) Appl. No.: 13/061,153

(22) PCT Filed: Sep. 18, 2009
(86) PCT No.: PCT/JP2009/004715

§ 371 Date: Feb. 28, 2011

(30) Foreign Application Priority Data
Sep. 26, 2008 (JP) 2008-248242

(51) Int. Cl. H05K 1/18; B32B 15/08; B32B 17/04; B32B 5/00; H05K 1/00

(52) U.S. Cl. 361/748; 428/457; 428/626; 428/418; 428/433; 428/335; 428/337; 174/250

(57) ABSTRACT

Disclosed is a laminate including an insulating resin layer and a metallic foil formed in contact with the insulating resin layer. The laminate is characterized in that the interface stress between the insulating resin layer and the metallic foil represented by the following formula (1) is not more than 7×10⁴, when the tensile modulus of elasticity (A) of the metallic foil at 25° C. is not less than 30 GPa and not more than 60 GPa, the thermal expansion coefficient (B) of the metallic foil is not less than 10 ppm and not more than 30 ppm, the bending modulus of elasticity (C) of the insulating resin layer at 25° C. is not less than 20 GPa and not more than 35 GPa, and the thermal expansion coefficient (D) of the insulating resin layer in the XY direction from 25° C. to Tg is not less than 5 ppm and not more than 15 ppm,

Interface stress={(B)−(D)}×{(A)−(C)}×{Tg−25 [° C.]} Formula (1)

wherein, Tg represents the glass transition temperature of the insulating resin layer.

### TECHNICAL FIELD

The present invention relates to a laminate, a circuit board and a semiconductor device.

### BACKGROUND ART

With recent reduction in a size and higher functions of electronic equipment, materials used for printed wiring boards to be mounted thereon require qualities capable of coping with reduction in a size, thinning, high integration, high layer count and high heat resistance. In response to these requirements, warpage in a printed wiring board becomes a problem.

When warpage occurs in a printed wiring board, in the mounting process, there might be drawbacks such as defective mounting of components, connection failure, sticking at a production line and the like. Furthermore, even for a product after mounting, when a printed wiring board is warped at a thermal cycling test, a stress is easily exerted between a printed wiring board and a mounting component, so that disconnection of through holes and disconnection of component connecting portions are easily made.

A main factor of warpage occurred in a printed wiring board may be uneven distribution of residual ratio of copper in wiring pattern, component position, surface resist opening ratio and the like.

Furthermore, other factors may be a stress at the time of lamination molding of a laminate constituting a printed wiring board, a displacement of thickness of a resin component by being impregnated into a base material constituting the laminate, and the like. As a countermeasure thereof, a method of adding an inorganic filler to the resin component has been conducted (for example, Patent Document 1). However, the use of a high-rigidity base material might cause a new problem of deterioration of punching or the like, so that a laminate with small warpage before and after mounting has been in demand.
Japanese Patent Application Laid-Open No. 2005-048036

### DISCLOSURE OF THE INVENTION

### Problems to be Solved by the Invention

As a printed wiring board, there are provided a laminate and a circuit board which are reduced in warpage and are excellent in mounting reliability.

### Means for Solving the Problems

Such objects have been achieved by the present invention as described in the following (1) to (17):

[1] A laminate including an insulating resin layer and a metallic foil formed in contact with the insulating resin layer, wherein the interface stress between said insulating resin layer and said metallic foil represented by the following formula (1) is not more than 7×10⁴, when the tensile modulus of elasticity (A) of said metallic foil at 25° C. is not less than 30 GPa and not more than 60 GPa, the thermal expansion coefficient (B) of said metallic foil is not less than 10 ppm and not more than 30 ppm, the bending modulus of elasticity (C) of said insulating resin layer at 25° C. is not less than 20 GPa and not more than 35 GPa, and the thermal expansion coefficient (D) of said insulating resin layer in the XY direction from 25° C. to Tg is not less than 5 ppm and not more than 15 ppm,

Interface stress={(B)−(D)}×{(A)−(C)}×{Tg−25 [° C.]} Formula (1)

wherein, Tg represents the glass transition temperature of said insulating resin layer.

[2] The laminate as set forth in [1], wherein said interface stress is not more than 2×10⁴.

[3] The laminate as set forth in [1] or [2], wherein said metallic foil is a copper foil.

[4] The laminate as set forth in any one of [1] to [3], wherein said metallic foil contains a plating film.

[5] The laminate as set forth in any one of [1] to [4], wherein said insulating resin layer contains a prepreg formed by impregnating a base material with the resin composition.

[6] The laminate as set forth in [5], wherein said resin composition contains an epoxy resin.

[7] The laminate as set forth in [5] or [6], wherein said resin composition contains a cyanate resin.

[8] The laminate as set forth in [7], wherein said cyanate resin is a novolac type cyanate resin represented by the following general formula (I),

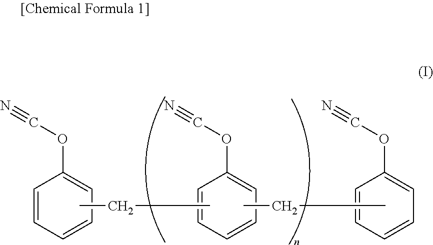

wherein, n is an arbitrary integer.

[9] The laminate as set forth in [7] or [8], wherein the content of said cyanate resin is not less than 5% by weight and not more than 50% by weight, based on the total weight of said resin composition.

[10] The laminate as set forth in [6], wherein the content of said epoxy resin is not less than 1% by weight and not more than 55% by weight, based on the total weight of said resin composition.

[11] The laminate as set forth in any one of [5] to [10], wherein said resin composition contains an inorganic filler.

[12] The laminate as set forth in [11], wherein the content of said inorganic filler is not less than 20% by weight and not more than 80% by weight, based on the total weight of said resin composition.

[13] The laminate as set forth in any one of [5] to [12], wherein said base material is a glass fiber base material.

[14] The laminate as set forth in any one of [1] to [13], wherein the thickness of said metallic foil is not less than 1 μm and not more than 70 μm.

[15] The laminate as set forth in any one of [1] to [14], wherein the thickness of said insulating resin layer is not less than 10 μm and not more than 1,000 μm.

[16] A circuit board, obtained by circuit processing of the laminate as set forth in any one of [1] to [15].

[17] A semiconductor device, manufactured by mounting a semiconductor element on the circuit board as set forth in [16].

In the meantime, any combination of the above-described components, or conversion of the expression of the present invention between methods, devices and the like is also effective as an aspect of the invention.

### Effect of the Invention

According to the present invention, a laminate and a circuit board which are reduced in warpage and are excellent in mounting reliability can be provided as a printed wiring board.

### BEST MODE FOR CARRYING OUT THE INVENTION

Hereinafter, the laminate and the circuit board of the present invention will be described.

The laminate of the present invention is composed of a metallic foil and an insulating resin layer. The metallic foil is formed in contact with the insulating resin layer. Furthermore, this metallic foil may be formed so as to cover the entire surface or apart of the insulating resin layer. In addition, the metallic foil may be formed on one surface or both surfaces of the insulating resin layer. For example, the laminate may a double-sided copper clad laminate or a circuit board.

The tensile modulus of elasticity (A) of the metallic foil at 25° C. is not less than 30 GPa and not more than 60 GPa, and further preferably not less than 35 GPa and not more than 50 GPa. When the tensile modulus of elasticity is within this range, it is possible to prepare a laminate with small warpage after circuit processing.

For example, the tensile modulus of elasticity (A) of the metallic foil may be controlled by changing the crystal size of the metal (copper) in the metallic foil. For example, when the crystal size of the metal (copper) is increased, the elastic modulus is decreased. When the crystal size is reduced, the elastic modulus is increased.

Herein, for example, the crystal size of the metal (copper) may be controlled by adjusting the conditions of electrolytic plating.

A plating film which is prepared by subjecting a component material (metal) of the metallic foil to electrolytic plating can be obtained from the metallic foil according to the present invention.

To measure the tensile modulus of elasticity (A) of the metallic foil, for example, an autograph may be used. Specifically, first of all, a sample is prepared in accordance with JIS Z 2201. The shape of the sample may be measured in accordance with JIS Z 2201 with No. 13 test piece by using an autograph (a product of Shimadzu Corporation).

Furthermore, the thermal expansion coefficient (B) of the metallic foil is preferably not less than 10 ppm and not more than 30 ppm, and further preferably not less than 10 ppm and not more than 20 ppm. When the thermal expansion coefficient is within this range, there can be obtained a laminate in which a difference in the thermal expansion rate of the metallic foil and the insulating resin layer is small and the warpage is small at the time of chip mounting.

A metal constituting the metallic foil is not particularly limited, and examples thereof include iron, nickel, copper, aluminum and the like. Among these, a copper foil is preferably used as a metallic foil. Impurities contained in the course of the manufacturing process of the copper foil are allowed.

For example, the thermal expansion coefficient (B) of the metallic foil may be controlled by changing the kind of the metallic foil. For example, a value of the thermal expansion coefficient (B) of aluminum is 24 ppm, while a value of the thermal expansion coefficient (B) of copper is about 17 ppm.

To measure the thermal expansion coefficient (B), for example, a TMA (thermal mechanical analysis) device may be used. Specifically, a test piece having a size of 4 mm×20 mm may be prepared from an electrolytic metallic foil (copper foil) and heated at a rate of 10° C./min using a TMA (thermal mechanical analysis) device (a product of TA Instrument Inc.) to measure the thermal expansion coefficient (B).

The bending elastic modulus (C) of the insulating resin layer at 25° C. is not less than 20 GPa and not more than 35 GPa, and further preferably not less than 25 GPa and not more than 35 GPa. When the bending elastic modulus is within this range, there can be obtained a laminate which is hardly affected by the metallic foil and is reduced in warpage after the production of a circuit.

Furthermore, the thermal expansion coefficient (D) of the insulating resin layer in the XY direction from 25° C. to Tg is not less than 5 ppm and not more than 15 ppm, and further preferably not less than 5 ppm and not more than 10 ppm. When the thermal expansion coefficient is within this range, there can be obtained a laminate in which a difference in the thermal expansion rate of the insulating resin layer and the chip is small and the warpage is small at the time of chip mounting.

For example, the bending elastic modulus (C) of the insulating resin layer or the thermal expansion coefficient (D) of the insulating resin layer may be controlled by changing the content of a filler constituting the insulating resin layer, the proportion of the glass cloth in the prepreg, the composition of the glass, the kind of the resin and the like.

For example, when the filler content is increased, the bending elastic modulus (C) of the insulating resin layer may be increased. When a cyanate resin is used as a resin, the bending elastic modulus (C) of the insulating resin layer may be increased.

A Dynamic Mechanical Analysis device (DMA) (DMA983, a Dynamic Mechanical Analysis device, manufactured by TA Instrument Inc.) may be used for the measurement of the bending elastic modulus (C) of the insulating resin layer. Specifically, the entire surface of a copper clad laminate was subjected to etching to prepare a sample having a width of 15 mm, a thickness of 0.1 mm and a length of 25 mm to measure the bending elastic modulus (C) in accordance with JIS K 6911 using a DMA device.

On the other hand, a TMA (thermal mechanical analysis) device may be used for the measurement of the thermal expansion coefficient (D) of the insulating resin layer. Specifically, the entire surface of a copper clad laminate was subjected to etching to prepare a test piece having a size of 4 mm×20 mm from a substrate obtained by stripping the copper foil. The thermal expansion coefficient (D) may be measured by heating the test piece at a rate of 10° C./min using a TMA (thermal mechanical analysis) device (a product of TA Instrument Inc.).

When the tensile modulus of elasticity of the above metallic foil at 25° C. is (A), the thermal expansion coefficient of the above metallic foil is (B), the bending elastic modulus of the above insulating resin layer at 25° C. is (C), and the thermal expansion coefficient of the above insulating resin layer in the XY direction from 25° C. to Tg is (D), the interface stress (interface stress parameter) represented by the following formula (I) may be not more than 7×10⁴, and further preferably not more than 2×10⁴, indicating a difference in the stress at an interface between the metallic foil and the insulating resin layer,

Interface stress={(B)−(D)}×{(A)−(C)}×{Tg−25 [° C.]} Formula (1)

wherein, Tg represents the glass transition temperature of the insulating resin layer.

Herein, the interface stress value represents an absolute value.

When the interface stress is not more than 7×10⁴, the warpage as a circuit board and the warpage after mounting may be reduced due to the interface stress between the metallic foil and the insulating resin layer or the metallic foil and the mounting component, and the reliability of a component mounting board may be enhanced.

Furthermore, when the interface stress is not more than 2×10⁴, the peel strength between the metallic foil and the insulating resin layer may be further enhanced. Accordingly, even though the formation of the metallic foil is changed, adhesive properties of the laminate are high, so that a laminate is excellent in the reliability. In this way, the laminate is obtained as designed, so that the production margin of the laminate in the present invention may be enhanced.

A DMA device may be used for the measurement of the glass transition temperature Tg of the insulating resin layer.

In one of conventional methods for producing a metallic foil clad laminate, as disclosed in Patent Document 1, a metallic foil clad laminate is formed by laminating a metallic foil on one surface or both surfaces of a high-rigidity base material and then heating them under pressure. In the past, in the technical field using such a high-rigidity base material, a high-elasticity metallic foil of from about 80 GPa to 110 GPa has been generally used as a typical example of the metallic foil in view of the productivity so as to prevent the metallic foil from being creased and to have excellent handling properties. Accordingly, Patent Document 1 does not describe the elastic modulus of the metallic foil in detail, but from the viewpoint of the productivity described above, a metallic foil of from about 80 GPa to 110 GPa has been used in the Patent Document 1.

However, the present inventors have studied and as a result, have newly found that even a slight warpage occurred before and after mounting may cause a problem when a high-elasticity metallic foil is used for a high-rigidity base material, under the present situation where high specification is required.

In the present invention, a low-elasticity metallic foil instead of a high-elasticity one has been used for a high-rigidity insulating resin layer as described above. Accordingly, it is possible to reduce a difference in the interface stress between (i) the metallic foil and the insulating resin layer, or (ii) the metallic foil and the mounting component. Thus, warpage before and after mounting may be suppressed. In this way, in the present invention, a laminate excellent in the reliability can be obtained. Herein, the use of a high-rigidity insulating resin layer may reduce a difference in the interface stress between (iii) the insulating resin layer and the mounting component, and can obtain a laminate excellent in the reliability.

The insulating resin layer according to the present invention comprises a prepreg by impregnating a base material (fibrous base material) with the resin component (resin composition).

Hereinafter, the resin composition, the prepreg and the laminate according to the present invention will be described in detail.

The resin composition according to the present invention is used to form a sheet-shaped prepreg by impregnating a base material with the resin composition, and the composition comprises a resin and/or its prepolymer. Furthermore, the prepreg according to the present invention is formed by impregnating a fibrous base material with the resin composition described above. Furthermore, the insulating resin layer used for the laminate of the present invention is formed by molding one or more of the above-described prepregs.

Hereinafter, the resin composition according to the present invention will be described.

The resin composition is not particularly limited, but it is preferable that the resin composition contains a thermosetting resin. Accordingly, heat resistance of the prepreg may be enhanced.

Examples of the thermosetting resin include novolac type phenol resins such as phenol novolac resins, cresol novolac resins, bisphenol A novolac resins and the like; phenol resins including resol type phenol resins such as unmodified resol phenol resins, oil-modified resol phenol resins modified with wood oil, flaxseed oil or walnut oil and the like; bisphenol type epoxy resins such as bisphenol A type epoxy resins, bisphenol F type epoxy resins, bisphenol S type epoxy resins, bisphenol E type epoxy resins, bisphenol M type epoxy resins, bisphenol P type epoxy resins, bisphenol Z type epoxy resins and the like; novolac type epoxy resins such as phenol novolac type epoxy resins, cresol novolac epoxy resins and the like; epoxy resins such as biphenyl type epoxy resins, biphenylaralkyl type epoxy resins, arylalkylene type epoxy resins, naphthalene type epoxy resins, anthracene type epoxy resins, phenoxy type epoxy resins, dicyclopentadiene type epoxy resins, norbornene type epoxy resins, adamantane type epoxy resins, fluorene type epoxy resins and the like; triazine-containing resins such as urea resins, melamine resins and the like; unsaturated polyester resins; bismaleimide resins; polyurethane resins; diallyl phthalate resins; silicone resins; benzoxazine-containing resins; cyanate resins; and the like.

These may be used alone, two or more of these having different weight average molecular weights may be combined, or one or more of these may be combined with a prepolymer thereof.

Among these, a cyanate resin (including a prepolymer for a cyanate resin) is particularly preferable. Accordingly, the use of a cyanate resin may reduce the thermal expansion coefficient of the prepreg. Furthermore, a cyanate resin exhibits excellent electric properties (a low dielectric constant, a low dielectric tangent), mechanical strength of the prepreg and so on.

The above-described cyanate resin is not particularly limited, but may be obtained by, for example, reacting a halogenated cyanogen compound with a phenol compound to give prepolymers from these by an appropriate method such as heating or the like as necessary. Specific examples include bisphenol type cyanate resins such as novolac type cyanate resins, bisphenol A type cyanate resins, bisphenol E type cyanate resins, tetramethyl bisphenol F type cyanate resins and the like. These resins may be used alone, or a plurality of kinds may be used in combination.

Among these, novolac type cyanate resins are preferable. Accordingly, the use of a novolac type cyanate resin may increase a crosslink density, resulting in improvement in heat resistance, and thus flame resistance of a resin composition or the like. One of the reasons may be formation of a triazine ring after curing a novolac type cyanate resin. Another possible reason is that a novolac type cyanate resin tends to easily carbonize due to a higher benzene-ring proportion in its structure. Furthermore, even when a thickness of a prepreg is not more than 0.5 mm, a laminate prepared by curing the prepreg may exhibit excellent rigidity. In particular, such a laminate exhibits excellent rigidity during heating and is thus highly reliable during mounting a semiconductor element.

The above novolac type cyanate resin may be, for example, a compound represented by the formula (I),

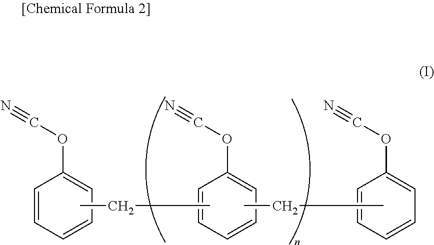

wherein, n is an arbitrary integer.

An average repeating unit number n of the novolac type cyanate resin represented by the above formula (I) is not particularly limited, but it is preferably from 1 to 10, and particularly preferably from 2 to 7 (hereinafter, “to” represents both upper and lower numbers, unless otherwise particularly specified). If the average repeating unit number n is less than the aforementioned lower limit, the novolac type cyanate resin may exhibit poor heat resistance, leading to elimination or evaporation of low molecular-weight materials during heating in some cases. If the average repeating unit number n exceeds the aforementioned upper limit, the melt viscosity may be so increased that molding properties of a prepreg may be deteriorated in some cases.

The weight average molecular weight of the cyanate resin is not particularly limited, but the weight average molecular weight is preferably from 500 to 4,500 and particularly preferably from 600 to 3,000. If the weight average molecular weight is less than the above lower limit, a produced prepreg has tack property, and in the case of contacting, prepregs may adhere to each other or resin transfer may be caused in some cases. If the weight average molecular weight exceeds the above upper limit, a reaction speed is so high that molding for forming a substrate (particularly, a circuit board) may be defective or interlayer peel strength may be deteriorated in some cases.

The weight average molecular weight of the cyanate resin may be measured by, for example, GPC (gel permeation chromatography, standard material: converted to polystyrene).

Although there are no particular restrictions, the cyanate resins may be used alone, two or more of these having different weight average molecular weights may be combined, or one or more of these may be combined with a prepolymer thereof.

The content of the thermosetting resin (for example, a cyanate resin) is not particularly limited, but it is preferably from 5 to 50% by weight, and particularly preferably from 20 to 40% by weight, based on the total weight of the resin composition. If the content is less than the above lower limit, formation of a prepreg may be difficult in some cases and if the content exceeds the above upper limit, strength of a prepreg may be deteriorated in some cases.

The resin composition preferably contains an inorganic filler. Accordingly, even a thinned laminate (for example, a thickness of not more than 0.5 mm) may be excellent in strength. Furthermore, low thermal expansion of a laminate may also be improved.

Examples of the inorganic filler include silicates such as talc, calcined clay, uncalcined clay, mica, glass and the like; oxides such as titanium oxide, alumina, silica, fused silica and the like; carbonates such as calcium carbonate, magnesium carbonate, hydrotalcite and the like; hydroxides such as aluminum hydroxide, magnesium hydroxide, calcium hydroxide and the like; sulfates or sulfites such as barium sulfate, calcium sulfate, calcium sulfite and the like; borates such as zinc borate, barium metaborate, aluminum borate, calcium borate, sodium borate and the like; nitrides such as aluminum nitride, boron nitride, silicon nitride, carbon nitride and the like; and titanates such as strontium titanate, barium titanate and the like. As an inorganic filler, these may be used alone or in combination of two or more kinds thereof. Among these, silica is preferable and fused silica (especially, spherical fused silica) is particularly preferable in the light of excellent low thermal expansion. A shape of fused silica may be crushed or spherical. In order to ensure its ability to impregnate a fibrous base material, it can be used in a way suitable for an expected purpose; for example, using spherical silica for reducing the melt viscosity of a resin composition.

An average particle size of the inorganic filler is not particularly limited, but it is preferably from 0.01 to 5.0 μm, and particularly preferably from 0.1 to 2.0 μm. If a particle size of the inorganic filler is less than the above lower limit, a varnish becomes so viscous that workability during the formation of a prepreg may be affected in some cases. If a particle size of the inorganic filler exceeds the above upper limit, disadvantageous phenomena such as precipitation of the inorganic filler in a varnish may occur in some cases.

This average particle size may be measured by, for example, a particle size distribution analyzer (LA-500, manufactured by Horiba, Ltd.).

This inorganic filler is not particularly limited, and the inorganic filler may be used from inorganic fillers in which an average particle size is monodisperse and inorganic fillers in which an average particle size is polydisperse. Alternatively, inorganic fillers in which an average particle size is monodisperse and/or polydisperse may be used alone or in combination of two or more kinds thereof.

Furthermore, an inorganic filler is preferably spherical silica (especially, spherical fused silica) having an average particle size of not more than 5.0 μm, particularly preferably spherical fused silica having an average particle size of 0.01 to 2.0 μm. Thus, filling properties of an inorganic filler may be improved.

The content of the inorganic filler is not particularly limited, but it is preferably from 20 to 80% by weight, and particularly preferably from 30 to 70% by weight, based on the total weight of the resin composition. When the content is within the above range, the layer may particularly have low thermal expansion and may be less hygroscopic.

When a cyanate resin (especially, a novolac type cyanate resin) is used as the thermosetting resin, it is preferable that an epoxy resin (substantially free from halogen) is used. The epoxy resin is not particularly limited, and examples thereof include bisphenol A type epoxy resins, bisphenol F type epoxy resins, bisphenol S type epoxy resins, phenol novolac type epoxy resins, cresol novolac type epoxy resins, biphenyl type epoxy resins, arylalkylene type epoxy resins, naphthalene type epoxy resins, triphenolmethane type epoxy resins, alicyclic epoxy resins and copolymers thereof. These may be used alone or a plurality of these may be used in combination.

As an epoxy resin, among these, two or more of these having different weight average molecular weights may be combined, or one or more of these may be combined with a prepolymer thereof.

The content of the epoxy resin is not particularly limited, but it is preferably from 1 to 55% by weight, and particularly preferably from 2 to 40% by weight, based on the total weight of the resin composition. If the content of the epoxy resin is less than the above lower limit, the cyanate resin may be less reactive or a product formed may exhibit deteriorated resistance to humidity in some cases. If the content exceeds the above upper limit, heat resistance may be deteriorated in some cases.

The weight average molecular weight of the epoxy resin is not particularly limited, but the weight average molecular weight is preferably from 500 to 20,000 and particularly preferably from 800 to 15,000. If the weight average molecular weight is less than the above lower limit, a prepreg may have tack property in some cases, and if it exceeds the above upper limit, its ability to impregnate a fibrous base material during the formation of a prepreg may be so deteriorated that a homogeneous product cannot be prepared in some cases.

The weight average molecular weight of the epoxy resin may be measured by, for example, GPC.

When a cyanate resin (especially, a novolac type cyanate resin) is used as the thermosetting resin, it is preferable that a phenol resin may be used. Examples of the phenol resin include novolac type phenol resins, resol type phenol resins, arylalkylene type phenol resins and the like. As the phenol resin, these may be used alone, two or more of these having different weight average molecular weights may be combined, or one or more of these may be combined with a prepolymer thereof. Among these, an arylalkylene type phenol resin is particularly preferable. Thus, solder heat resistance after moisture absorption may be improved.

The content of the phenol resin is not particularly limited, but it is preferably from 1 to 55% by weight, and particularly preferably from 5 to 40% by weight, based on the total weight of the resin composition. If the content of the phenol resin is less than the above lower limit, heat resistance may be deteriorated in some cases, and if the content exceeds the above upper limit, properties of low thermal expansion may be deteriorated in some cases.

The weight average molecular weight of the phenol resin is not particularly limited, but the weight average molecular weight is preferably from 400 to 18,000, and particularly preferably from 500 to 15,000. When the weight average molecular weight is less than the above lower limit, a prepreg may have tack property in some cases, and if it exceeds the above upper limit, its ability to impregnate a fibrous base material during the formation of a prepreg may be so deteriorated that a homogeneous product cannot be prepared in some cases.

The weight average molecular weight of the phenol resin may be measured by, for example, GPC.

The resin composition is not particularly limited, it is preferable that a coupling agent is used. The use of a coupling agent may improve wettability of an interface between the thermosetting resin and the inorganic filler, so that the thermosetting resin and the inorganic filler can be homogeneously settled on the fibrous base material, and heat resistance, particularly solder heat resistance after water absorption, may be improved.

The coupling agent may be used from those commonly used as a coupling agent. Specifically, one or more coupling agents may be preferably used, which are selected from epoxysilane coupling agents, cationic silane coupling agents, aminosilane coupling agents, titanate coupling agents and silicone oil coupling agents. Accordingly, wettability of an interface of the inorganic filler may be improved and heat resistance may be further improved.

The amount of the coupling agent added depends on the specific surface area of the inorganic filler, so it is not particularly limited. However, it is preferably from 0.05 to 3 parts by weight, and particularly preferably from 0.1 to 2 parts by weight, based on 100 parts by weight of the inorganic filler. When the content is less than the aforementioned lower limit, the inorganic filler cannot be sufficiently covered, so that its effect of improving heat resistance may be deteriorated in some cases, and if the content exceeds the above upper limit, it may influence the reaction, leading to deterioration of bending strength in some cases.

In the resin composition, a hardening accelerator may be used, as necessary. As the hardening accelerator, known hardening accelerators may be used. Examples thereof include organometallic salts such as zinc naphthenate, cobalt naphthenate, zinc octylate, cobalt octylate, cobalt (II) bisacetylacetonate, cobalt (III) trisacetylacetonate and the like; tertiary amines such as triethylamine, tributylamine, diazabicyclo[2,2,2]octane and the like; imidazoles such as 2-phenyl-4-methylimidazole, 2-ethyl-4-ethylimidazole, 2-phenyl-4-methylimidazole, 2-phenyl-4-methyl-5-hydroxyimidazole, 2-phenyl-4,5-dihydroxyimidazole and the like; phenol compounds such as phenol, bisphenol A, nonylphenol and the like; organic acids such as acetic acid, benzoic acid, salicylic acid, para-toluenesulfonic acid and the like; and mixtures thereof. As a hardening accelerator, these including their derivatives may be used alone or two or more kinds including their derivatives may be used in combination.

The content of the hardening accelerator is not particularly limited, but it is preferably from 0.05 to 5% by weight, and particularly preferably from 0.2 to 2% by weight, based on the total weight of the resin composition. When the content is less than the above lower limit, its effect of accelerating hardening may not be exhibited in some cases, and when it exceeds the above upper limit, storage stability of the prepreg may be deteriorated in some cases.

The resin composition may be used together with thermoplastic resins such as a phenoxy resin, a polyimide resin, a polyamideimide resin, a polyphenylene oxide resin, a polyether sulfone resin, a polyester resin, a polyethylene resin, a polystyrene resin and the like; polystyrene thermoplastic elastomers such as a styrene-butadiene copolymer, a styrene-isoprene copolymer and the like; thermoplastic elastomers such as a polyolefin thermoplastic elastomer, a polyamide elastomer, a polyester elastomer and the like; and diene elastomers such as polybutadiene, epoxy-modified polybutadiene, acryl-modified polybutadiene, methacryl-modified polybutadiene and the like.

The above resin composition may contain, if necessary, additives other than those components described above, such as pigments, dyes, deforming agents, leveling agents, ultraviolet absorbing agents, foaming agents, antioxidants, flame retardants, ion scavengers and the like.

Next, the prepreg will be described.

The prepreg according to the present invention is formed by impregnating a base material with the resin composition described above. Accordingly, it is possible to obtain a prepreg exhibiting various excellent properties such as dielectric properties and reliability in mechanical and electric connection under high temperature and high humidity conditions, and suitable for the preparation of a printed wiring board.

Examples of the fibrous base material used in the present invention include a glass fibrous base material such as a glass cloth, a glass nonwoven fabric and the like; a polyamide resin fiber such as a polyamide resin fiber, an aromatic polyamide resin fiber, a wholly aromatic polyamide resin fiber and the like; a polyester type resin fiber such as a polyester resin fiber, an aromatic polyester resin fiber, a wholly aromatic polyester resin fiber and the like; a synthetic fibrous base material composed of woven cloth or nonwoven fabric containing a polyimide resin fiber or a fluororesin fiber or the like as a main constituent; and an organic fibrous base material such as a paper base material containing a craft paper, a cotton linter paper or mixed paper of a linter and a craft pulp or the like as a main constituent. Among these, a glass fiber base material is preferably used. The use of a glass fiber base material may enhance the strength and water absorption coefficient of the prepreg. Furthermore, the thermal expansion coefficient of the prepreg may be decreased.

A fibrous base material may be impregnated with the resin composition obtained in the present invention by, for example, using the resin composition according to the present invention to prepare a resin varnish and immersing the fibrous base material in the resin varnish, coating using any of various coaters, spraying using a spray or the like. Among these methods, preferred is immersing a fibrous base material in a resin varnish. Thus, impregnating ability of the resin composition to the fibrous base material may be improved. When a fibrous base material is immersed in a resin varnish, a common impregnating application apparatus may be used.

It is desirable that a solvent used for the resin varnish may easily dissolve the resin component in the resin composition, but a poor solvent may be used as long as it does not adversely affect the process. Examples of a solvent exhibiting good dissolving ability include acetone, methyl ethyl ketone, methyl isobutyl ketone, cyclohexanone, tetrahydrofuran, dimethylformamide, dimethylacetamide, dimethyl sulfoxide, ethylene glycol, cellosolves, carbitols and the like.

A solid content in the resin varnish is not particularly limited, but it is preferably from 40 to 80% by weight, and particularly preferably from 50 to 65% by weight, on the basis of the solid content in the resin composition. Thus, impregnating ability of the resin varnish to a fibrous base material may be further improved. The fibrous base material may be impregnated with the resin composition and dried at a predetermined temperature of, for example, 80 to 200° C. to provide a prepreg.

Next, the laminate of the present invention will be described.

The insulating resin layer constituting the laminate of the present invention is formed using at least one prepreg. When one prepreg is used, a metallic foil is laminated on one surface or both surfaces of the prepreg. When one prepreg is used, a film may be laminated on one surface thereof.

Furthermore, two or more prepregs may be laminated. When two or more prepregs are laminated, a metallic foil or a film is laminated on one surface or both surfaces of the outermost surfaces of the laminated prepregs.

Next, the laminate of the present invention may be formed by heating the prepreg (insulating resin layer) laminated with the metallic foil or the like under pressure.

The heating temperature is not particularly limited, but it is preferably from 150 to 240° C., and particularly preferably from 180 to 220° C.

The pressure is not particularly limited, but it is preferably from 2 to 5 MPa, and particularly preferably from 2.5 to 4 MPa.

Examples of the metallic foil used for the laminate of the present invention include iron, aluminum, stainless steel, copper, alloys containing one or more kinds thereof and the like. Among these, it is preferable to use copper as a metallic foil in view of electric properties. A thickness of the metallic foil is not particularly limited, but it is preferably not less than 1 μm and not more than 70 μm, and particularly preferably not less than 5 μm and not more than 18 μm.

A thickness of the insulating resin layer used for the laminate of the present invention is preferably not less than 10 μm and not more than 1,000 μm, and more preferably not less than 20 μm and not more than 500 μm.

Examples of the film include polyethylene, polypropylene, polyethylene terephthalate, polyimide, fluororesins and the like.

Then, the circuit board of the present invention will be described.

The circuit board of the present invention is obtained by forming a conductor circuit by etching the metallic foil of the laminate. On the conductor circuit, an insulation coating layer is formed so as to cover the conductor circuit.

Next, the semiconductor device of the present invention will be described.

The semiconductor device using the circuit board is not particularly limited, and examples thereof include a semiconductor device in which a circuit board and a semiconductor element are connected by bonding wires, a flip chip type semiconductor device in which a circuit board and a semiconductor element are connected through solder bumps, and the like. Hereinafter, one of flip chip type semiconductor devices will be exemplified.

The flip chip type semiconductor device is obtained by mounting a semiconductor element having solder bumps on the circuit board, and connecting the circuit board and the semiconductor element via solder bumps. Then, a liquid encapsulating resin fills between the circuit board and the semiconductor element to form a semiconductor device. It is preferable that the solder bumps are composed of an alloy including tin, lead, silver, copper, bismuth or the like. To connect the semiconductor element and the circuit board, a connecting electrode section on the circuit board and solder bumps of the semiconductor element are positioned using a flip chip bonder or the like, and then the solder bumps are heated to the melting point or more using an IR reflow apparatus, a heat plate, or other heating apparatus, and the circuit board and the solder bumps are connected by subjecting them to a melt-bonding process.

Furthermore, in order to improve connection reliability, a metal layer having a relatively low melting point such as a solder paste or the like may be previously formed on the connecting electrode section on the circuit board. Ahead of this bonding step, solder bumps and/or the surface layer of the connecting electrode section on the circuit board may be coated with a flux, so that connection reliability can also be improved.

### EXAMPLES

Hereinafter, the present invention will be described by way of Examples and Comparative Examples. However, the present invention is not restricted to these Examples and Comparative Examples.

### Example 1

(1) Preparation of Resin Varnish

14.7 parts by weight of a novolac type cyanate resin (Primaset PT-30, manufactured by Lonza Japan, Ltd., weight average molecular weight: about 700), 8 parts by weight of a biphenyldimethylene type epoxy resin (NC-3000H, manufactured by Nippon Kayaku Co., Ltd., epoxy equivalent: 275), 7 parts by weight of a biphenyldimethylene type phenol resin (MEH-7851-3H, manufactured by Meiwa Plastic Industries, Ltd., hydroxyl equivalent: 230), and 0.3 parts by weight of an epoxysilane type coupling agent (A-187, manufactured by GE Toshiba Silicones Co., Ltd.) were dissolved in methyl ethyl ketone at an ambient temperature, and 70 parts by weight of spherical fused silica (SO-25R, manufactured by Admatechs Co., Ltd., average particle size: 0.5 μm) was added to the mixture. The resulting mixture was stirred for 10 minutes using a high-speed stirrer to obtain a resin varnish.

(2) Preparation of Prepreg

A glass cloth (WEA-2116, manufactured by Nitto Boseki Co., Ltd., thickness: 94 μm) was impregnated with the resin varnish obtained above, and was dried in a heating furnace at a temperature of 150° C. for 2 minutes. Thus, a prepreg was prepared, in which a varnish solid content was about 50% by weight in the prepreg. The thickness of the resulting prepreg was 0.1 mm.

(3) Preparation of Laminate

An electrolytic copper foil (HLB, manufactured by Nippon Denkai, Ltd.) having a thickness of 12 μm and having a tensile modulus of elasticity at 25° C. of 30 GPa was overlaid on both surfaces of the above prepreg, and then they were molded by heating under pressure at a temperature of 200° C. under a pressure of 4 MPa for 2 hours. Thus, a double-sided copper clad laminate having a thickness of 0.124 mm was prepared.

(4) Preparation of Circuit Board

A predetermined circuit was created on the resulting laminate by a usual circuit creation process (perforating, plating, DFR laminate, exposure and development, etching, DFR strip).

(5) Preparation of Package Substrate

Openings were formed in the insulating layer of the above circuit board using a CO₂ laser device, and the surface of the insulating layer was subjected to an outer layer circuit forming process by electrolytic copper plating, so that the outer layer circuit and the inner layer circuit were electrically connected. Incidentally, a connecting electrode section was arranged on the outer layer circuit in order to mount a semiconductor element.

Thereafter, a solder resist (PSR4000/AUS308, manufactured by Taiyo Ink MFG. Co., Ltd.) was formed on the outermost layer, and the connecting electrode section was exposed so as to mount the semiconductor element thereon by exposure and development, and subjected to a nickel gold plating process to cut it in a size of 50 mm×50 mm. Thus, a package substrate was prepared.

(6) Preparation of Semiconductor Device

A semiconductor element (TEG chip, size: 15 mm×15 mm, thickness: 0.8 mm, thermal expansion coefficient (CTE): 3 ppm) having a solder bump composed of Sn/Pb eutectic crystal and a circuit protecting layer composed of a positive photosensitive resin (CRC-8300, manufactured by Sumitomo Bakelite Co., Ltd.) was employed for the semiconductor element. For assembly of the semiconductor device, first of all, a flux material was uniformly applied over such a solder bump by a transfer process. Next, such a semiconductor element was disposed on the above-described package substrate, and a heating process and a compressively bonding process were carried out with a flip-chip bonder. Next, the solder bump was melted with an IR reflow furnace to be joined to the substrate. Then, such a semiconductor element was encapsulated with a liquid encapsulating resin (CRP-4152S, manufactured by Sumitomo Bakelite Co., Ltd.), and then the liquid encapsulating resin was cured to obtain a semiconductor device. In addition to above, the cure of the liquid encapsulating resin was conducted by heating under conditions of a temperature of 150° C. and a period of 120 minutes.

### Example 2

A semiconductor device was obtained in the same manner as in Example 1, except that 19.7 parts by weight of a novolac type cyanate resin (Primaset PT-30, manufactured by Lonza Japan, Ltd., weight average molecular weight: about 700), 11 parts by weight of a biphenyldimethylene type epoxy resin (NC-3000H, manufactured by Nippon Kayaku Co., Ltd., epoxy equivalent: 275), 9 parts by weight of a biphenyldimethylene type phenol resin (MEH-7851-3H, manufactured by Meiwa Plastic Industries, Ltd., hydroxyl equivalent: 230), and 0.3 parts by weight of an epoxysilane type coupling agent (A-187, manufactured by GE Toshiba Silicones Co., Ltd.) were dissolved in methyl ethyl ketone at an ambient temperature, and 60 parts by weight of spherical fused silica (SO-25R, manufactured by Admatechs Co., Ltd., average particle size: 0.5 μm) was used.

### Example 3

A semiconductor device was obtained in the same manner as in Example 2, except that an electrolytic copper foil (3EC-M3-VLP, manufactured by Mitsui Kinzoku Co., Ltd.) having a tensile modulus of elasticity at 25° C. of 60 GPa was used.

### Example 4

A semiconductor device was obtained in the same manner as in Example 1, except that 15.45 parts by weight of a biphenylaralkyl-modified phenol novolac type epoxy resin (NC-3000H, manufactured by Nippon Kayaku Co., Ltd., epoxy equivalent: 275), 27 parts by weight of a p-xylene-modified naphthol aralkyl type cyanate resin induced from an α-naphthol aralkyl resin (SN485, manufactured by Nippon Steel Chemical Co., Ltd.) of the following formula, 2.25 parts by weight of naphthalenediol glycidyl ether (HP4032, manufactured by DaiNippon Ink and Chemicals, Inc.), and 0.3 parts by weight of an epoxysilane type coupling agent (A-187, manufactured by GE Toshiba Silicones Co., Ltd.) were dissolved in methyl ethyl ketone at an ambient temperature, and 55 parts by weight of spherical fused silica (SO-25R, manufactured by Admatechs Co., Ltd., average particle size: 0.5 μm) was used.

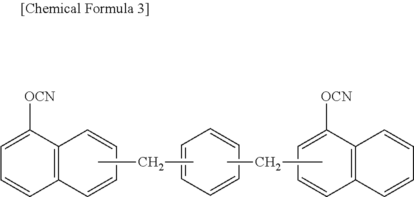

### Example 5

A semiconductor device was obtained in the same manner as in Example 1, except that 17.2 parts by weight of a biphenylaralkyl-modified phenol novolac type epoxy resin (NC-3000H, manufactured by Nippon Kayaku Co., Ltd., epoxy equivalent: 275), 12.25 parts by weight of a p-xylene-modified naphthol aralkyl type cyanate resin induced from an α-naphthol aralkyl resin (SN485, manufactured by Nippon Steel Chemical Co., Ltd.) of the above formula, 5.25 parts by weight of bis(3-ethyl-5-methyl-maleimide phenyl)methane (BMI-70, manufactured by K•I Chemical Industry Co., Ltd.), and 0.3 parts by weight of an epoxysilane type coupling agent (A-187, manufactured by GE Toshiba Silicones Co., Ltd.) were dissolved in methyl ethyl ketone at an ambient temperature, and 65 parts by weight of spherical fused silica (SO-25R, manufactured by Admatechs Co., Ltd., average particle size: 0.5 μm) was used.

### Example 6

A semiconductor device was obtained in the same manner as in Example 1, except that 15.95 parts by weight of a biphenylaralkyl-modified phenol novolac type epoxy resin (NC-3000H, manufactured by Nippon Kayaku Co., Ltd., epoxy equivalent: 275), 13.13 parts by weight of a p-xylene-modified naphthol aralkyl type cyanate resin induced from an α-naphthol aralkyl resin (SN485, manufactured by Nippon Steel Chemical Co., Ltd.) of the above formula, 1.88 parts by weight of naphthalenediol glycidyl ether (HP4032, manufactured by DaiNippon Ink and Chemicals, Inc.), 8.75 parts by weight of bis(3-ethyl-5-methyl-maleimide phenyl)methane (BMI-70, manufactured by K•I Chemical Industry Co., Ltd.), and 0.3 parts by weight of an epoxysilane type coupling agent (A-187, manufactured by GE Toshiba Silicones Co., Ltd.) were dissolved in methyl ethyl ketone at an ambient temperature, and 60 parts by weight of spherical fused silica (SO-25R, manufactured by Admatechs Co., Ltd., average particle size: 0.5 μm) was used.

### Example 7

A semiconductor device was obtained in the same manner as in Example 1, except that 22.8 parts by weight of a cresol novolac type epoxy resin (N690, manufactured by DaiNippon Ink and Chemicals, Inc.), 12.2 parts by weight of a phenol novolac resin (Phenolite LF2882, manufactured by DaiNippon Ink and Chemicals, Inc.), 0.3 parts by weight of a curing agent (EH-3636AS, manufactured by ADEKA Corporation), and 0.3 parts by weight of an epoxysilane type coupling agent (A-187, manufactured by GE Toshiba Silicones Co., Ltd.) were dissolved in methyl ethyl ketone at an ambient temperature, and 65 parts by weight of spherical fused silica (SO-25R, manufactured by Admatechs Co., Ltd., average particle size: 0.5 μm) was used.

### Comparative Example 1

A semiconductor device was obtained in the same manner as in Example 2, except that an electrolytic copper foil (F2-WS, manufactured by Furukawa Electric Co., Ltd.) having a tensile modulus of elasticity at 25° C. of 80 GPa was used.

### Comparative Example 2

A semiconductor device was obtained in the same manner as in Example 2, except that an electrolytic copper foil (JTCAM, manufactured by Nippon Mining & Metals Co., Ltd.) having a tensile modulus of elasticity at 25° C. of 110 GPa was used.

### Comparative Example 3

A semiconductor device was obtained in the same manner as in Example 1, except that 21.7 parts by weight of a biphenyldimethylene type epoxy resin (NC-3000H, manufactured by Nippon Kayaku Co., Ltd., epoxy equivalent: 275), 18 parts by weight of a biphenyldimethylene type phenol resin (MEH-7851-3H, manufactured by Meiwa Plastic Industries, Ltd., hydroxyl equivalent: 230), and 0.3 parts by weight of an epoxysilane type coupling agent (A-187, manufactured by GE Toshiba Silicones Co., Ltd.) were dissolved in methyl ethyl ketone at an ambient temperature, 60 parts by weight of spherical fused silica (SO-25R, manufactured by Admatechs Co., Ltd., average particle size: 0.5 μm) was used, and an electrolytic copper foil having a tensile modulus of elasticity at 25° C. of 110 GPa was used.

### Comparative Example 4

A semiconductor device was obtained in the same manner as in Example 1, except that 38.4 parts by weight of a bisphenol A type epoxy resin (Epicoat 828, manufactured by Japan Epoxy Resins Co., Ltd.), 17 parts by weight of a modified phenol novolac resin (Phenolite LF2882, manufactured by DaiNippon Ink and Chemicals, Inc.), 0.3 parts by weight of a hardening accelerator 2PN-CZ (a product of Shikoku Chemicals Corporation), and 0.3 parts by weight of an epoxysilane type coupling agent (A-187, manufactured by GE Toshiba Silicones Co., Ltd.) were dissolved in methyl ethyl ketone at an ambient temperature, 40 parts by weight of spherical fused silica (SO-25R, manufactured by Admatechs Co., Ltd., average particle size: 0.5 μm) was used, and an electrolytic copper foil (F2-WS, manufactured by Furukawa Electric Co., Ltd.) having a tensile modulus of elasticity at 25° C. of 80 GPa was used.

Using the laminates and semiconductor devices prepared in Examples and Comparative Examples, evaluation tests were made. Evaluation items are described below. Evaluation results are shown in Table 1.

TABLE 1

| | Elastic | CTE of | Elastic | |
|---|---|---|---|---|
| | Modulus of | Copper | Modulus of | CTE of |
| | Copper Foil | Foil | Laminate | Laminate |
| | (A) | (B) | (C) | (D) |
| Example 1 | 30 | 17 | 30 | 6 |
| Example 2 | 30 | 17 | 28 | 10 |
| Example 3 | 60 | 17 | 28 | 10 |
| Example 4 | 30 | 17 | 28 | 10 |
| Example 5 | 30 | 17 | 28 | 10 |
| Example 6 | 30 | 17 | 28 | 10 |
| Example 7 | 30 | 17 | 25 | 12 |
| Comparative | 80 | 17 | 28 | 10 |
| Example 1 | | | | |
| Comparative | 110 | 17 | 28 | 10 |
| Example 2 | | | | |
| Comparative | 110 | 17 | 22 | 15 |
| Example 3 | | | | |
| Comparative | 80 | 17 | 18 | 16 |
| Example 4 | | | | |
| | Interface | | | |
| | Stress | Tg | Warpage of | Mounting |
| | Parameter | (DMA) | Laminate | Reliability |
| Example 1 | 0.0E+00 | 260 | A | A |
| Example 2 | 3.3E+03 | 260 | A | A |
| Example 3 | 5.3E+04 | 260 | A | A |
| Example 4 | 3.3E+03 | 260 | A | A |
| Example 5 | 3.3E+03 | 260 | A | A |
| Example 6 | 3.3E+03 | 260 | A | A |
| Example 7 | 4.9E+03 | 220 | A | A |
| Comparative | 8.6E+04 | 260 | B | B |
| Example 1 | | | | |
| Comparative | 1.3E+05 | 260 | C | B |
| Example 2 | | | | |
| Comparative | 2.2E+04 | 150 | A | C |
| Example 3 | | | | |
| Comparative | 1.0E+04 | 190 | A | C |
| Example 4 | | | | |

Evaluation Method

(1) Warpage of Laminate

A laminate having a size of 530 mm×530 mm was cut into 50 mm×50 mm pieces to obtain samples for warpage evaluation.

A warpage amount was measured under the conditions of a measurement area of 48 mm×48 mm, a measurement pitch of 4 mm (in both X and Y directions) and a temperature of 25° C. using a variable temperature laser three-dimensional measuring apparatus (LS220-MT100, manufactured by T-Tech Co. Ltd.). The warpage data thus obtained was subjected to slope correction by a least squares method, and a difference between the maximum and the minimum was defined as a warpage amount. The smaller a warpage amount indicates the smaller warpage.

A: Warpage of not more than 60 μm

B: Warpage of from 60 to 80 μm

C: Warpage exceeding 80 μm

(2) Mounting Reliability

The above-described semiconductor device was observed by eyes whether cracking occurred in the test piece or not by (i) applying 1,000 cycles (condition 1 for one cycle: −65° C. for 10 min, 150° C. for 10 min, −65° C. for 10 min); and (ii) applying 1,000 cycles (condition 2 for one cycle: −40° C. for 10 min, 125° C. for 10 min, −40° C. for 10 min), in

Fluorinert.

A: Under conditions 1 and 2, no cracking occurred.

B: Under condition 1, cracking occurred, but under condition 2, no cracking occurred.

C: Under conditions 1 and 2, cracking occurred.

(3) Tensile Modulus of Elasticity of Metallic Foil

A sample was prepared in accordance with JIS Z 2201. The shape of the sample was measured in accordance with JIS Z 2201 with No. 13 test piece by using an autograph (a product of Shimadzu Corporation).

(4) Thermal Expansion Coefficient (CTE) of Metallic Foil

A test piece having a size of 4 mm×20 mm was prepared from the above-described electrolytic copper foil, and heated at a rate of 10° C./min using a TMA (thermal mechanical analysis) device (a product of TA Instrument Inc.) to measure the thermal expansion coefficient.

(5) Bending Elastic Modulus of Insulating Resin Layer

The bending elastic module was measured in accordance with JIS K 6911. A sample having a width of 15 mm, a thickness of 0.1 mm and a length of 25 mm was used. The sample was obtained by etching the entire surface of the laminate.

(6) Thermal Expansion Coefficient (CTE) of Insulating Resin Layer

A test piece having a size of 4 mm×20 mm was prepared from a substrate prepared by etching the entire surface of the copper clad laminate, and heated at a rate of 10° C./min using a TMA (thermal mechanical analysis) device (a product of TA Instrument Inc.) to measure the thermal expansion coefficient.

(7) Glass Transition Temperature Tg of Insulating Resin Layer

A test piece having a size of 4 mm×20 mm was prepared from a substrate prepared by etching the entire surface of the copper clad laminate, and heated at a rate of 5° C./min using a Dynamic Mechanical Analysis device DMA983, manufactured by TA Instrument Inc., to measure the glass transition temperature. The glass transition temperature was determined from the peak position of tan δ.

As is apparent from Table 1, in Examples 1 to 7 using a metallic foil having a tensile modulus of elasticity of from 30 to 60 GPa, warpage of the laminate was small, and mounting reliability was improved when it was used for a semiconductor device. On the other hand, in Comparative Examples 1 to 3 using a metallic foil having a tensile modulus of elasticity exceeding 60 GPa, warpage was high and mounting reliability was low.

In Comparative Example 4 similar to Example 1 of Patent Document 1, a typical metallic foil of 80 GPa in the past was used for a high-rigidity base material (laminate). As a result, in Comparative Example 4, warpage in the laminate having a metallic foil and an insulating resin layer was small, but a stress was exerted between the insulating resin layer and the semiconductor element, and mounting reliability was also deteriorated because the thermal expansion coefficient of the insulating resin layer was higher than that of the present invention.

1. A laminate comprising an insulating resin layer and a metallic foil formed in contact with the insulating resin layer, wherein the interface stress between said insulating resin layer and said metallic foil represented by the following formula (I) is not more than 7×10⁴, when the tensile modulus of elasticity (A) of said metallic foil at 25° C. is not less than 30 GPa and not more than 60 GPa, the thermal expansion coefficient (B) of said metallic foil is not less than 10 ppm and not more than 30 ppm, the bending modulus of elasticity (C) of said insulating resin layer at 25° C. is not less than 20 GPa and not more than 35 GPa, and the thermal expansion coefficient (D) of said insulating resin layer in the XY direction from 25° C. to Tg is not less than 5 ppm and not more than 15 ppm,
Interface stress={(B)−(D)}×{(A)−(C)}×{Tg−25 [° C.]} Formula (1)
wherein, Tg represents the glass transition temperature of said insulating resin layer.

2. The laminate as set forth in claim 1, wherein said interface stress is not more than 2×10⁴.

3. The laminate as set forth in claim 1, wherein said metallic foil is a copper foil.

4. The laminate as set forth in claim 1, wherein said metallic foil contains a plating film.

5. The laminate as set forth in claim 1, wherein said insulating resin layer contains a prepreg formed by impregnating a base material with the resin composition.

6. The laminate as set forth in claim 5, wherein said resin composition contains an epoxy resin.

7. The laminate as set forth in claim 5, wherein said resin composition contains a cyanate resin.

8. The laminate as set forth in claim 7, wherein said cyanate resin is a novolac type cyanate resin represented by the following general formula (I), 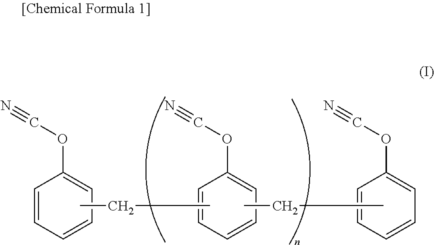
wherein, n is an arbitrary integer.

9. The laminate as set forth in claim 7, wherein the content of said cyanate resin is not less than 5% by weight and not more than 50% by weight, based on the total weight of said resin composition.

10. The laminate as set forth in claim 6, wherein the content of said epoxy resin is not less than 1% by weight and not more than 55% by weight, based on the total weight of said resin composition.

11. The laminate as set forth in claim 5, wherein said resin composition contains an inorganic filler.

12. The laminate as set forth in claim 11, wherein the content of said inorganic filler is not less than 20% by weight and not more than 80% by weight, based on the total weight of said resin composition.

13. The laminate as set forth in claim 5, wherein said base material is a glass fiber base material.

14. The laminate as set forth in claim 1, wherein the thickness of said metallic foil is not less than 1 μm and not more than 70 μm.

15. The laminate as set forth in claim 1, wherein the thickness of said insulating resin layer is not less than 10 μm and not more than 1,000 μm.

16. A circuit board, obtained by circuit processing of the laminate as set forth in claim 1.

17. A semiconductor device, manufactured by mounting a semiconductor element on the circuit board as set forth in claim 16.
